(19) United States
(12) Patent Application Publication
(10) Pub. No.: US 2026/0299357 A1
(43) Pub. Date: Oct. 1, 2026

(54) ELECTRONIC DEVICE

(71) Applicant: InnoLux Corporation, Miao-Li County (TW)

(72) Inventors: Cheng-Shen PAN, Miao-Li County (TW); Cheng-Min WU, Miao-Li County (TW); Yu-Lin HSIEH, Miao-Li County (TW); Heng-Cheng SONG, Miao-Li County (TW); Wen-Chi CHEN, Miao-Li County (TW)

(21) Appl. No.: 19/697,916

(22) Filed: Jun. 4, 2026

Related U.S. Application Data
(63) Continuation of application No. 18/176,185, filed on Feb. 28, 2023.

(30) Foreign Application Priority Data
Mar. 28, 2022 (CN) 202210314907.X

(51) Int. Cl. G02F 1/1339

(52) U.S. Cl. CPC G02F 1/1339; G02F 2201/503

(57) ABSTRACT

An electronic device is provided with an active area and a peripheral area, and includes a first substrate, a second substrate, a sealant frame, a conductive member and a wall structure. The first substrate has a first surface, a second surface opposite to the first surface, and a side surface connected between the first surface and the second surface. The second substrate is disposed opposite to the first surface of the first substrate, and has s third surface and a fourth surface opposite to the third surface. The sealant frame is disposed in the peripheral area surrounding the active area. The conductive member is disposed on the third surface of the second substrate and is in the peripheral area. The wall structure is disposed between the first substrate and the second substrate, wherein in a top view, the wall structure is disposed between the conductive member and the sealant frame. The color layer is disposed on the first surface of the first substrate. The conductive sealant includes a first part disposed on the second surface of the first substrate, a second part disposed on the side surface of the first substrate, and a third part disposed on the conductive member, wherein the second part is connected between the first part and the third part, and in the top view, the wall structure is disposed between the third part and the sealant frame.

### CROSS-REFERENCE TO RELATED APPLICATIONS

This application claims the benefits of the Chinese Patent Application Serial Number 202210314907.X, filed on Mar. 28, 2022, the subject matter of which is incorporated herein by reference. This application is a continuation (CA) of U.S. Patent application for “Electronic device comprising wall structure”, U.S. application Ser. No. 18/176,185 filed Feb. 28, 2023, and the subject matter of which is incorporated herein by reference.

### BACKGROUND

### Field of the Disclosure

The present disclosure relates to an electronic device and, more particularly, to an electronic device capable of reducing the infiltration of conductive sealant into the electronic device.

### Description of Related Art

Consumers are increasingly demanding narrow borders for electronic devices, such as display devices. Under the narrow border design, the size of the peripheral area of the electronic device is gradually reduced, and thus it is easy to cause the conductive sealant originally arranged on the periphery of the substrate to penetrate into the substrate, resulting in negatively affecting the circuit inside the substrate, for example, causing an electrostatic discharge fail (ESD fail).

Therefore, there is a need for an improved electronic device to mitigate and/or obviate the aforementioned problems.

### SUMMARY

The present disclosure provides an electronic device having an active area and a peripheral area, which includes: a first substrate; a second substrate arranged opposite to the first substrate; a sealant frame arranged in the peripheral area and surrounding the active area; a conductive member arranged in the peripheral area; and a wall structure arranged between the first substrate and the second substrate, wherein, when viewed in a top view direction, the wall structure is arranged between the sealant frame and the conductive member.

Other novel features of the disclosure will become more apparent from the following detailed description when taken in conjunction with the accompanying drawings.

### BRIEF DESCRIPTION OF DRAWINGS

FIG. 1 is a schematic diagram (top view) of the electronic device according to an embodiment of the present disclosure;

FIG. 2 is a cross-sectional view (front view) of the first region of the electronic device in FIG. 1 taking along line A-A′;

FIG. 3 is a schematic diagram (top view) of the first region of the electronic device in FIG. 1 according to an embodiment of the present disclosure;

FIG. 4 is a schematic diagram (top view) of a first region of the electronic device in FIG. 1 according to another embodiment of the present disclosure;

FIG. 5 is a schematic diagram (top view) of the first region of the electronic device in FIG. 1 according to still another embodiment of the present disclosure; and

FIG. 6 is a schematic diagram (top view) of the first region of the electronic device in FIG. 1 according to yet another embodiment of the present disclosure.

### DETAILED DESCRIPTION OF EMBODIMENT

The implementation of the present disclosure is illustrated by specific embodiments to enable persons skilled in the art to easily understand the other advantages and effects of the present disclosure by referring to the disclosure contained therein. The present disclosure is implemented or applied by other different, specific embodiments. Various modifications and changes can be made in accordance with different viewpoints and applications to details disclosed herein without departing from the spirit of the present disclosure.

It is noted that, in the specification and claims, unless otherwise specified, having “one” element is not limited to having a single said element, but one or more said elements may be provided.

In addition, in the specification and claims, unless otherwise specified, ordinal numbers, such as “first” and “second”, used herein are intended to distinguish components rather than disclose explicitly or implicitly that names of the components bear the wording of the ordinal numbers. The ordinal numbers do not imply what order a component and another component are in terms of space, time or steps of a manufacturing method. These ordinal numbers are used only to distinguish one element with a particular name from another element with the same name.

In addition, the term “adjacent” used herein may refer to describe mutual proximity and does not necessarily mean mutual contact.

In addition, the description of “when . . . ” or “while . . . ” in the present disclosure means “now, before, or after”, etc., and is not limited to occurrence at the same time. In the present disclosure, the similar description of “disposed on” or the like refers to the corresponding positional relationship between the two components, and does not limit whether there is contact between the two components, unless specifically limited. Furthermore, when the present disclosure recites multiple effects, if the word “or” is used between the effects, it means that the effects can exist independently, but it does not exclude that multiple effects can exist at the same time.

In addition, the terms “connect” or “couple” in the specification and claims not only refer to direct connection with another component, but also indirect connection with another component, or refer to electrical connection. Besides, the electrical connection may include a direct connection, an indirect connection, or a mode in which two components communicate through radio signals.

In addition, in the specification and claims, the term “almost”, “about”, “approximately” or “substantially” usually means within 20%, 10%, 5%, 3%, 2%, 1% or 0.5% of a given value or range. The quantity the given value is an approximate quantity, which means that the meaning of “almost”, “about”, “approximately” or “substantially” may still be implied in the absence of a specific description of “almost”, “about”, “approximately” or “substantially”. In addition, the terms “ranging from the first value to the second value” and “range between the first value and the second value” indicate that the range includes the first value, the second value, and other values between the first value and the second value.

In addition, the technical features of different embodiments disclosed in the present disclosure may be combined to form another embodiment.

In addition, the electronic device disclosed in the present disclosure may include a display device, a backlight device, an antenna device, a sensing device, a tiled device, a touch display device, a curved display device, or a free shape display device, but is not limited thereto. The electronic device may include liquid crystal, light emitting diode, fluorescence, phosphor, other suitable display medium, or a combination thereof, but it is not limited thereto. The display device may be a non-self-luminous display device or a self-luminous display device. The antenna device may be a liquid crystal antenna device or a non-liquid crystal antenna device, and the sensing device may be a sensor for sensing capacitance, light, heat or ultrasonic waves, but it is not limited thereto. Electronic components may include passive and active components, such as capacitors, resistors, inductors, diodes, transistors, etc. The diodes may include light emitting diodes (LEDs) or photodiodes. The light emitting diodes may include, for example, organic light emitting diodes (OLEDs), mini light emitting diodes (mini LEDs), micro light emitting diodes (micro LEDs), or quantum dot light emitting diodes (quantum do LEDs), but it is not limited thereto. The tiled device may be, for example, a display tiled device or an antenna tiled device, but it is not limited thereto. It is noted that, the electronic device may be any arrangement and combination of the foregoing, but it is not limited thereto. In addition, the electronic device may be a bendable or flexible electronic device. It is noted that, the electronic device may be any arrangement and combination of the foregoing, but it is not limited thereto. In addition, the appearance of the electronic device may be rectangular, circular, polygonal, a shape with curved edges, or other suitable shapes. The electronic device may be provided with a peripheral system such as a driving system, a control system, a light source system, a shelf system, etc. to support a display device, an antenna device or a tiled device. For the convenience of description, a display device will be used as the electronic device for description in the following, but the present disclosure is not limited thereto.

For the convenience of description, hereinafter, a first direction (e.g., X-direction), a second direction (e.g., Y-direction) and a third direction (e.g., Z-direction) will be used to assist in explaining the configuration of each element in the electronic device 1. The third direction (Z-direction) may be defined as a top view direction, and the top view direction may be, for example, the normal direction of the substrate of the electronic device 1 (e.g., first substrate 2), or parallel to the display direction of the electronic device 1, but it is not limited thereto. In addition, the first direction (X-direction), the second direction (Y-direction), and the third direction (Z-direction) may be substantially perpendicular to each other, but it is not limited thereto.

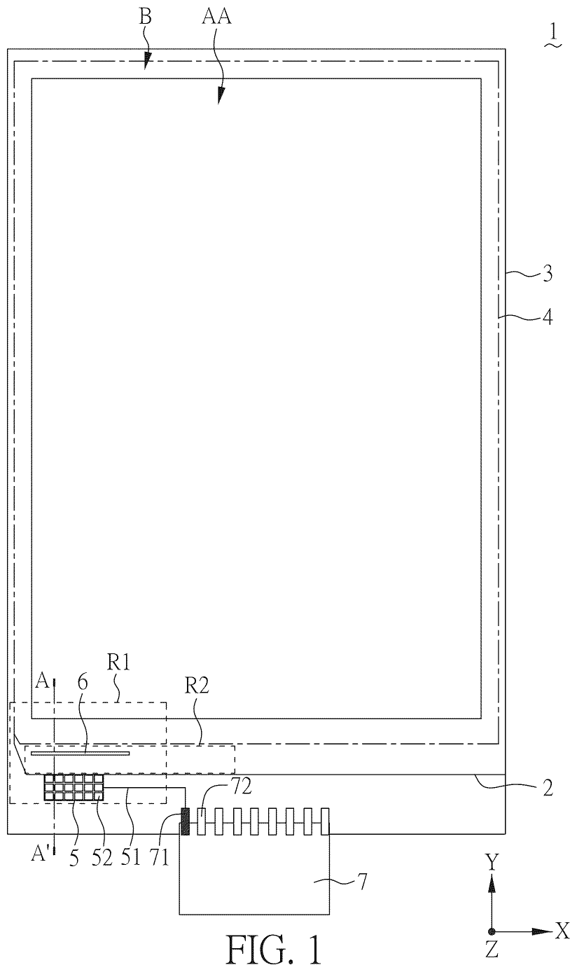

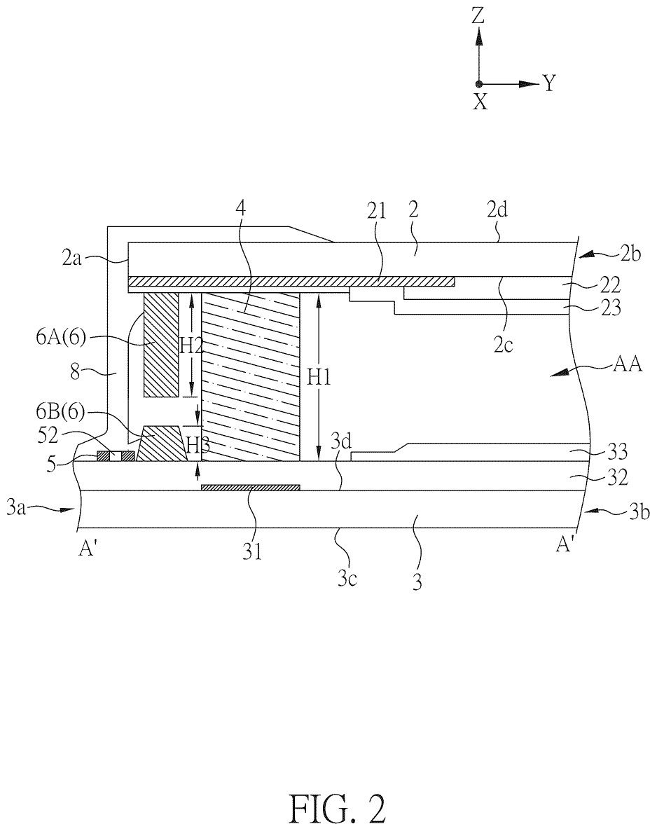

Please refer to FIG. 1 and FIG. 2. FIG. 1 is a schematic diagram (top view) of the electronic device according to an embodiment of the present disclosure, and FIG. 2 is a cross-sectional view (front view) of the first region of the electronic device in FIG. 1 taking along line A-A′. As shown in FIG. 1, the electronic device 1 has an active area AA and a peripheral area B. The active area AA may be regarded as an area of the electronic device 1 that has a pixel array, and the peripheral area B is an area beyond the active area AA, such as an area outside the active area AA, but it is not limited thereto. The electronic device 1 further includes a first substrate 2, a second substrate 3, a sealant frame 4, a conductive member 5 and a wall structure 6. When viewed in the top view direction, that is, viewed along the third direction (Z-direction), the sealant frame 4 may be disposed around the active area AA, the conductive member 5 is disposed in the peripheral area B, and the wall structure 6 is disposed between the sealant frame 4 and the conductive member 5. As shown in FIG. 2, in the cross-sectional view of the first region taking along line A-A′, the first substrate 2 and the second substrate 3 are disposed opposite to each other in the third direction (Z-direction). The sealant frame 4 is disposed between the first substrate 2 and the second substrate 3. The conductive member 5 may be disposed on the first substrate 2, and at least part of the conductive member 5 is disposed between the first substrate 2 and the second substrate 3. The wall structure 6 is disposed between the first substrate 2 and the second substrate 3.

As shown in FIG. 1, in one embodiment, the electronic device 1 may further include a circuit board 7, wherein the circuit board 7 includes a dummy pad 71 and a conductive pad 72. The dummy pad 71 may not be electrically connected with the signal line (not shown), and the conductive pad 72 may be electrically connected with the signal line (not shown), wherein the signal line (not shown) may be the wire that transmits signals to control the electronic device. Herein, the dummy pad 71 is defined as, for example, the pad through which no signal passes when the electronic device 1 is operating, and the conductive pad 72 is defined as, for example, the pad through which a signal passes when the electronic device 1 is operating. In addition, in one embodiment, the conductive member 5 and the dummy pad 71 may be connected through a conductive wire 51, wherein the conductive wire 51 may be grounded to discharge the static electricity accumulated in the conductive member 5, but it is not limited thereto. As shown in FIG. 2, the electronic device 1 may further include a conductive sealant 8. The conductive sealant 8 may be electrically connected to the conductive member 5, and the conductive sealant 8 may be in contact with the wall structure 6 due to flow. In some embodiments, part of the conductive sealant 8 may be arranged between the first substrate 2 and the second substrate 3, and in contact with the conductive member 5. In other embodiments, part of the conductive sealant 8 may cover the first substrate 2 and contact the conductive member 5, but the present disclosure is not limited thereto.

In addition, please refer to FIG. 1 again. In one embodiment, when viewed in a top view direction, i.e., viewed along the third direction (Z-direction), the peripheral area B may be provided with a wall placement region R2, which is defined as a maximum region where the wall structure 6 may be installed. For example, the wall placement region R2 may allow a plurality of wall structures 6 to be placed, and the plurality of wall structures 6 may be in the wall placement region R2 and arranged along the first direction (X-direction) or the second direction (Y-direction), while the present disclosure is not limited thereto. In addition, in one embodiment, the wall placement region R2 may be disposed between the sealant frame 4 and the first side 2a (shown in FIG. 2) of the first substrate 2, but it is not limited thereto.

With the arrangement of the wall structure 6, when the conductive sealant 8 flows toward the interior of the electronic device 1 (for example, from the peripheral area B to the active area AA), the wall structure 6 may block at least part of the conductive sealant 8, so that the conductive sealant 8 does not easily flow into the electronic device 1. Alternatively, when the sealant frame 4 expands outward, the wall structure 6 may also block at least part of the sealant frame 4, thereby reducing the possibility of panel cutting failure.

Next, the internal structure of the electronic device 1 will be described in detail.

As shown in FIG. 2, the first substrate 2 has a first side 2a, a second side 2b, a third side 2c and a fourth side 2d, wherein the first side 2a of the first substrate 2 is opposite to the second side 2b of the first substrate 2, and the third side 2c of the first substrate 2 is opposite to the fourth side 2d of the first substrate 2. In addition, the second substrate 3 has a first side 3a, a second side 3b, a third side 3c and a fourth side 3d, wherein the first side 3a of the second substrate 3 is opposite to the second side 3b of the second substrate 3, and the third side 3c of the second substrate 3 is opposite to the fourth side 3d of the second substrate 3. It is noted that part of the structure is omitted in FIG. 2, and thus the second side 2b of the first substrate 2, the first side 3a of the third substrate 3 and the second side 3b of the third substrate 3 are indicated by arrows for their relative positions.

In addition, a black matrix layer 21 and a pigment layer 22 are each arranged on the third side 2c of the first substrate 2. A first alignment layer 23 is arranged on the black matrix layer 21 and the pigment layer 22. An electrode layer 31 and an insulating layer 32 are respectively arranged on the fourth side 3d of the second substrate 3. A second alignment layer 33 is arranged on the insulating layer 32, wherein the second alignment layer 33 faces the first alignment layer 23. The sealant frame 4 and the wall structure 6 may be each arranged between the black matrix layer 21 and the insulating layer 32. The conductive member 5 may be arranged on the insulating layer 32. The conductive sealant 8 may be arranged on the fourth side 2d of the first substrate 2, and may extend to the insulating layer 32 along the fourth side 4d of the first substrate 2, the first side 2a of the first substrate 2, and the black matrix layer 21, thereby being electrically connected to the conductive member 5.

In addition, in the second direction (Y-direction), the wall structure 6 may be disposed between the sealant frame 4 and the conductive sealant 8, and the wall structure 6 may be disposed between the electrode layer 31 and the conductive sealant 8. As a result, it is able to reduce the influence of the conductive sealant 8 on the electrode layer 31.

Next, the details of each component will be described.

Regarding the first substrate 2, in one embodiment, the first substrate 2 may include a thin-film transistor (TFT) substrate, a color-filter-on-array substrate or a color filter substrate, but it is not limited thereto. The first substrate 2 may include a flexible substrate or a non-flexible substrate, and its material may include glass, quartz, sapphire substrate, polycarbonate (PC), polyimide (PI), polypropylene (PP), polyethylene terephthalate (PET), other suitable materials, or a combination of the aforementioned materials, but it is not limited thereto. In addition, in some embodiments, the black matrix layer 21, the pigment layer 22 or the first alignment layer 23 may be selectively arranged on the first substrate 2 according to the requirements, but it is not limited thereto.

Regarding the second substrate 3, in one embodiment, the second substrate 3 may include a thin film transistor substrate, a color-filter-on-array substrate or a color filter substrate, but it is not limited thereto. The second substrate 3 may include a flexible substrate or a non-flexible substrate, and its material may include glass, quartz, sapphire substrate, polycarbonate, polyimide, polypropylene, polyethylene terephthalate, and other suitable material or a combination of the aforementioned materials, but it is not limited thereto. In addition, in some embodiments, the electrode layer 31, the insulating layer 32 or the second alignment layer 33 may be selectively arranged on the second substrate 3 according to the requirements, but it is not limited thereto.

Regarding the sealant frame 4, in one embodiment, the material of the sealant frame 4 may include metal, plastic, other suitable materials or a combination of the aforementioned materials, but it is not limited thereto. In one embodiment, the edge of the sealant frame 4 may be continuously formed, so that the sealant frame 4 may be, for example, a ring-shaped sealant frame. In another embodiment, the edge of the sealant frame 4 may be broken, so the sealant frame 4 may include a plurality of micro sealant frames arranged at intervals along the edge of the active area AA, but it is not limited thereto. As shown in FIG. 2, the sealant frame 4 may have a sealant frame height H1 in the third direction (Z-direction); that is, the shortest distance between a side of the sealant frame 4 adjacent to the first substrate 2 and a side of the sealant frame 4 adjacent to the second substrate 3 is defined as the sealant frame height H1. In one embodiment, the sealant frame height H1 may be between 3 micrometers and 3.2 micrometers (i.e., 3 μm≤H1≤3.2 μm), but it is not limited thereto. In one embodiment, the sealant frame height H1 of may be substantially the same as the height of a dummy cell gap of the electronic device 1, but it is not limited thereto.

Regarding the conductive member 5, in one embodiment, the conductive member 5 may be, for example, a conductive pad or a wire. As shown in FIG. 1 and FIG. 2, in one embodiment, when viewed from a top view, the conductive member 5 may include at least one opening 52, and the conductive adhesive 8 may be used to fill the at least one opening 52. The conductive member 5 may be provided with an opening 52 to reduce the possibility that the conductive member 5 is likely to cause ESD fail due to an excessively large conductive area. In another embodiment, when the conductive member 5 is designed to be integrated with other objects (such as a two-dimensional barcode) in order to save space, the conductive member 5 may not have the opening 52.

Regarding the wall structure 6, as shown in FIG. 2, in one embodiment, the wall structure 6 may include a wall 6A, wherein the wall 6A may be arranged on the third side 2c of the first substrate 2 and extend toward the second substrate 3. In one embodiment, the wall structure 6 may include a wall 6B, wherein the wall 6B may be arranged on the fourth side 3d of the second substrate 3 and extend toward the first substrate 2. In one embodiment, the wall structure 6 may include the wall 6A and the wall 6B at the same time, but in another embodiment, the wall 6A and the wall 6B may exist independently. In one embodiment, the wall 6A and the wall 6B may be connected together.

In addition, the wall 6A may have a height H2 in the third direction (Z-direction); that is, the shortest distance between a side of the first portion 6A adjacent to the first substrate 2 and a side of the first portion 6A adjacent to the second substrate 3 is defined as the height H2. In one embodiment, the height H2 of the wall 6A may be between 2.5 μm and 2.7 μm (i.e., 2.5 μm≤H2≤2.7 μm), but it is not limited thereto. It is noted that the height H2 of the wall 6A may be smaller than the sealant frame height H1. In addition, the wall 6B may have a height H3 in the third direction (Z-direction); that is, the shortest distance between a side of the wall 6B adjacent to the first substrate 2 and a side of the wall 6B adjacent to the second substrate 3 is defined as the height H3. In one embodiment, the height H3 of the wall 6B may be between 2 μm and 2.2 μm (i.e., 2 μm≤H3≤2.2 μm), but it is not limited thereto. It is noted that the height H3 of the wall 6B may be smaller than the sealant frame height H1. In addition, when the wall 6A and the wall 6B exist at the same time, the sum of the height H2 of the wall 6A and the height H3 of the wall 6B is smaller than or equal to the sealant frame height H1 (i.e., H2+H3≤H1). In addition, in one embodiment, the first portion 6A and the second portion 6B are connected to form a single wall structure 6, and the height of the single wall structure 6 may be equal to the sealant frame height H1.

In one embodiment, the material of the wall 6A or the wall 6B may include silicon nitride (SiNx), silicon oxide (SiO), organic materials, other suitable materials, or a combination of the aforementioned materials, while it is not limited thereto. In one embodiment, when the wall 6A is arranged on the first substrate 2 and the wall 6B is arranged on the second substrate 3, the material of the wall 6A may be silicon nitride (SiNx) or an organic material, while it is not limited thereto.

In addition, as shown in FIG. 2, the contour shape of the wall 6A or the wall 6B projected in the first direction (X-direction) may be a column shape or a trapezoid shape, while it is not limited thereto. In one embodiment, the contour edge of the wall 6A or the wall 6B projected in the first direction (X-direction) may be a step shape with a height difference, or may also be a gentle slope shape, while it is not limited thereto.

Regarding the circuit board 7, in one embodiment, the circuit board 7 may be, for example, a flexible printed circuit (FPC), or may be configured in a chip on film (COF) manner, while it is not limited thereto.

Regarding the conductive sealant 8, in one embodiment, the conductive sealant 8 may include various conductive particles, and the material of the conductive particles may include gold, silver, copper, aluminum, zinc, iron, nickel, graphite, conductive compounds, other suitable materials or a combination of the aforementioned materials, while it is not limited thereto.

Therefore, the details of the various components can be understood.

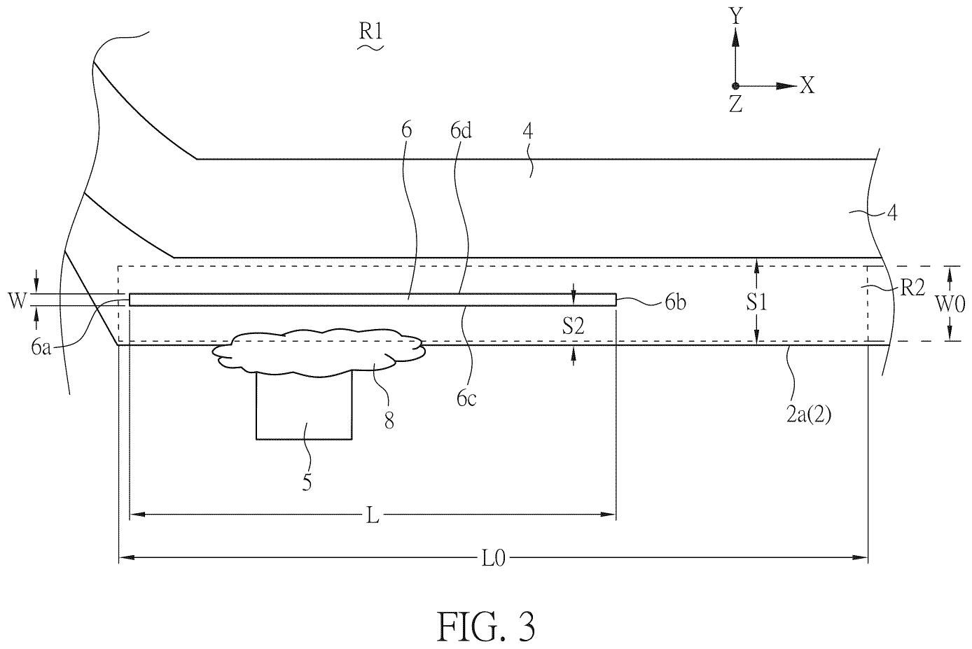

Next, the configuration of the wall structure 6 will be described, and please refer to FIG. 1 to FIG. 3 at the same time. FIG. 3 is a detailed schematic diagram (top view) of a first region R1 of the electronic device 1 in FIG. 1 according to an embodiment of the present disclosure.

As shown in FIG. 3, when viewed in a top view direction, i.e., viewed along the third direction (Z-direction), the wall structure 6 is arranged between the sealant frame 4 and the first side 2a (shown in FIG. 2) of the first substrate 2. The wall structure 6 may be a long strip shape, and has a first side 6a, a second side 6b, a third side 6c and a fourth side 6d, wherein the first side 6a is opposite to the second side 6b, and the third side 6c is opposite to the fourth side 6d.

The wall structure 6 extends from the first side 6a to the second side 6b along the first direction (X-direction). The wall structure 6 may have a wall length L in the first direction (X-direction), wherein the wall length L is defined as the shortest distance between the first side 6a and the second side 6b in the first direction (X-direction). In one embodiment, the wall length L may be between 50 μm and 150 μm (i.e., 50 μm≤L≤150 μm), but it is not limited thereto. In addition, in the second direction (Y-direction), the wall structure 6 may have a width, hereinafter referred to as the wall width W, which may be defined as the shortest distance between the third side 6c and the fourth side 6d in the second direction (Y-direction). In one embodiment, the wall width W may be between 25 μm and 100 μm (i.e., 25 μm≤W≤100 μm), but it is not limited thereto. In one embodiment, the wall width W may be between 20 μm and 30 μm (i.e., 20 μm≤W≤30 μm), but it is not limited thereto.

In the second direction (Y-direction), there is a shortest distance between the sealant frame 4 and the first side 2a of the first substrate 2, hereinafter referred to as the first distance S1. In one embodiment, the first distance S1 may be between 50 μm and 200 μm (i.e., 50 μm≤S1≤200 μm), but it is not limited thereto. In addition, there is a shortest distance between the wall structure 6 and the first side 2a of the first substrate 2 in the second direction (Y-direction), that is, the shortest distance between the third side 6c of the wall structure 6 and the first side 2a of the first substrate 2, which is hereinafter referred to as the second distance S2. In one embodiment, the second distance S2 may be between 10 μm and 20 μm (i.e., 10 μm≤S2≤20 μm), but it is not limited thereto. In one embodiment, the second distance S2 may be between 12.5 μm and 17.5 μm (i.e., 12.5 μm≤S2≤17.5 μm), but it is not limited thereto. In one embodiment, the second distance S2 may be substantially 15 μm (i.e., S2=15 μm).

In one embodiment, a plurality of wall structures 6 may be arranged in the wall placement region R2, wherein the plurality of wall structures 6 may be arranged along the first direction (X-direction) or the second direction (Y-direction), which are, for example but not limited to, connected to each other or spaced apart. In addition, the wall placement region R2 may have an extension length L0 (marked in FIG. 3) in the first direction (X-direction), wherein the extension length L0 may be greater than or equal to the wall length L. In one embodiment, the extension length L0 is smaller than or equal to 1500 μm (i.e., L0≤1500 μm), but it is not limited thereto. In addition, the wall placement region R2 has an extension width W0 in the second direction (Y-direction), and the extension width W0 may be smaller than or equal to the first distance S1 (i.e., the shortest distance between the sealant frame 4 and the first side 2a of the first substrate 2), while it is not limited thereto.

With the arrangement of the embodiment in FIG. 3, the wall structure 6 may be used to block at least part of the conductive sealant 8 from flowing to the circuit inside the electronic device 1 (e.g., to the electrode layer 31 in FIG. 2). As a result, the arrangement of the wall structure 6 can be understood.

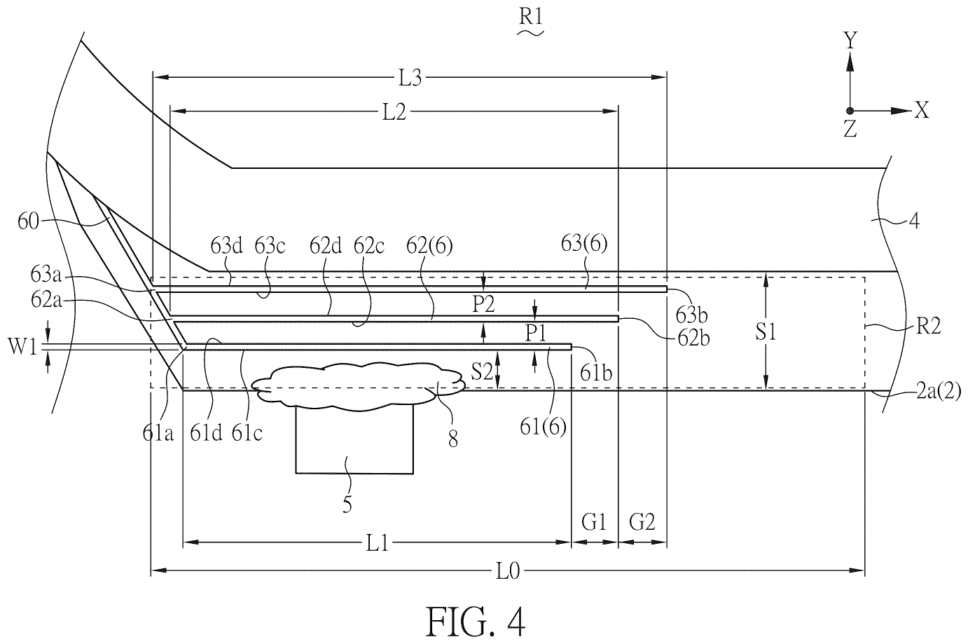

The wall structure 6 of the present disclosure may also have different implementation aspects, and please refer to FIG. 1 to FIG. 4 at the same time. FIG. 4 is a detailed schematic diagram (top view) of the first region R1 of the electronic device 1 in FIG. 1 according to another embodiment of the present disclosure.

As shown in FIG. 4, the wall structure 6 may include a plurality of walls, for example, at least two, and three walls are exemplified in this embodiment. In this embodiment, the wall structure 6 may include a first wall 61, a second wall 62 and a third wall 63. When viewed from a top view, the first wall 61, the second wall 62 or the third wall 63 may be a long strip shape, but it is not limited thereto. In the second direction (Y-direction), the second wall 62 is arranged between the first wall 61 and the third wall 63. In the second direction (Y-direction), the first wall 61, the second wall 62 and the third wall 63 may be arranged between the sealant frame 4 and the first side 2a of the second substrate 2. In addition, the wall placement region R2 and the first distance S1 between the sealant frame 4 and the first side 2a of the second substrate 2 in this embodiment may be figured out from the description of the embodiment in FIG. 3, and thus a detailed description is deemed unnecessary.

The first wall 61 has a first side 61a, a second side 61b, a third side 61c and a fourth side 61d, wherein the first side 61a is opposite to the second side 61b, the third side 61c is opposite to the fourth side 61d, the third side 61c is away from the sealant frame 4, and the fourth side 61d is adjacent to the sealant frame 4. The second wall 62 has a first side 62a, a second side 62b, a third side 62c and a fourth side 62d, wherein the first side 62a is opposite to the second side 62b, the third side 62c is opposite to the fourth side 62d, the third side 62c is away from the sealant frame 4, and the fourth side 62d is adjacent to the sealant frame 4. The third wall 63 has a first side 63a, a second side 63b, a third side 63c and a fourth side 63d, wherein the first side 63a is opposite to the second side 63b, the third side 63c is opposite to the fourth side 63d, the third side 63c is away from the sealant frame 4, and the fourth side 63d is adjacent to the sealant frame 4.

In the first direction (X), the length extending from the first side 61a to the second side 61b of the first wall 61 in the first direction (X-direction) is a first wall length L1, the length extending from the first side 62a to the second side 62b of the wall 62 in the first direction (X-direction) is a second wall length L2, and the length extending from the first side 63a to the second side 63b of the third wall 63 in the first direction (X-direction) is a third wall length L3. In one embodiment, the first wall length L1 may be between 10 μm and 50 μm (i.e., 10 μm≤L1≤50 μm), but it is not limited thereto. In one embodiment, the second wall length L2 may be between 10 μm and 50 μm (i.e., 10 μm≤L2≤50 μm), but it is not limited thereto. In one embodiment, the third wall length L3 may be between 10 μm and 50 μm (i.e., 10 μm≤L3≤50 μm), but it is not limited thereto. In one embodiment, the first wall length L1 is smaller than or equal to the second wall length L2 (i.e., L1≤L2), and the second wall length L2 is smaller than or equal to the third wall length L3 (L2≤L3).

In addition, in one embodiment, the second side 61b of the first wall 61 is closer to the second side 62b of the second wall 62 than the first side 61a of the first wall 61, and there is a shortest distance between the second side 61b of the first wall 61 and the second side 62b of the second wall 62 in the first direction (X-direction), which is hereinafter referred to as the third distance G1. The third distance G1 is parallel to the first direction (X-direction). In one embodiment, the third distance G1 is between 6 μm and 50 μm (i.e., 6 μm≤G1≤50 μm), but it is not limited thereto. In addition, in one embodiment, the second side 62b of the second wall 62 is closer to the second side 63b of the third wall 63 than the first side 61b of the second wall 62, and there is a shortest distance between the second side 62b of the second wall 62 and the third side 63b of the third wall 63 in the first direction (X-direction), which is hereinafter referred to as the fourth distance G2. The fourth distance G2 is parallel to the first direction (X-direction). In one embodiment, the fourth distance G2 is between 6 μm and 50 μm (i.e., 6 μm≤G1≤50 μm), but it is not limited thereto. In one embodiment, the third distance G1 may be equal to the fourth distance G2, but it is not limited thereto.

The first wall 61 has a wall width W1 in the second direction (Y-direction). In one embodiment, the wall width W1 may be between 20 μm and 50 μm (i.e., 20 μm≤W1≤50 μm), but it is not limited thereto. In one embodiment, the wall width W1 may be between 20 μm and 30 μm (i.e., 20 μm≤W1≤30 μm), but it is not limited thereto. In one embodiment, the second wall 62 or the third wall 63 also has a wall width W1 in the second direction (Y-direction). In one embodiment, the wall width W1 of the first wall 61, the wall width W1 of the second wall 62, and the wall width W1 of the third wall 63 may be equal or different.

In the second direction (Y-direction), a shortest distance between the third side 61c of the first wall 61 and the first side 2a of the first substrate 2 may be regarded as the second distance S2. In one embodiment, the second distance S2 may be figured out from the description of the embodiment in FIG. 3, and thus a detailed description is deemed unnecessary.

In addition, in the second direction (Y-direction), there is a shortest distance between the third side 61c of the first wall 61 and the third side 62c of the second wall 62, which is hereinafter referred to as a gap P1. In one embodiment, the gap P1 may be between 15 μm and 50 μm (i.e., 15 μm≤P1≤50 μm), but it is not limited thereto. In one embodiment, the gap P1 may be between 15 μm and 20 μm (i.e., 15 μm≤P1≤20 μm), but it is not limited thereto. In addition, there is a shortest distance between the third side 62c of the second wall 62 and the third side 63c of the third wall 63, which is hereinafter referred to as a gap P2. In one embodiment, the gap P2 may be between 15 μm and 50 μm (i.e., 15 μm≤P2≤50 μm), but it is not limited thereto. In one embodiment, the gap P2 may be between 15 μm and 20 μm (i.e., 15 μm≤P2≤20 μm), but it is not limited thereto. In one embodiment, the gap P1 and the gap P2 may be equal, but it is not limited thereto.

In addition, as shown in FIG. 4, the electronic device 1 may further include a side wall 60. When viewed in a top view direction, i.e., viewed along the third direction (Z-direction), the side wall 60 may be inclined, for example, to form an included angle with the first direction (X-direction) or the second direction (Y-direction). In one embodiment, the first side 61a of the first wall 61, the first side 62a of the second wall 62, and the third side 63a of the third wall 63 may be connected to different positions on the side wall 60, while it is not limited thereto. In one embodiment, the electronic device 1 may not have the side wall 60.

By arranging a plurality of walls 61, 62, 63 in the second direction (Y-direction), the effect of blocking the conductive sealant 8 or the sealant frame 4 by the wall structure 6 may be improved.

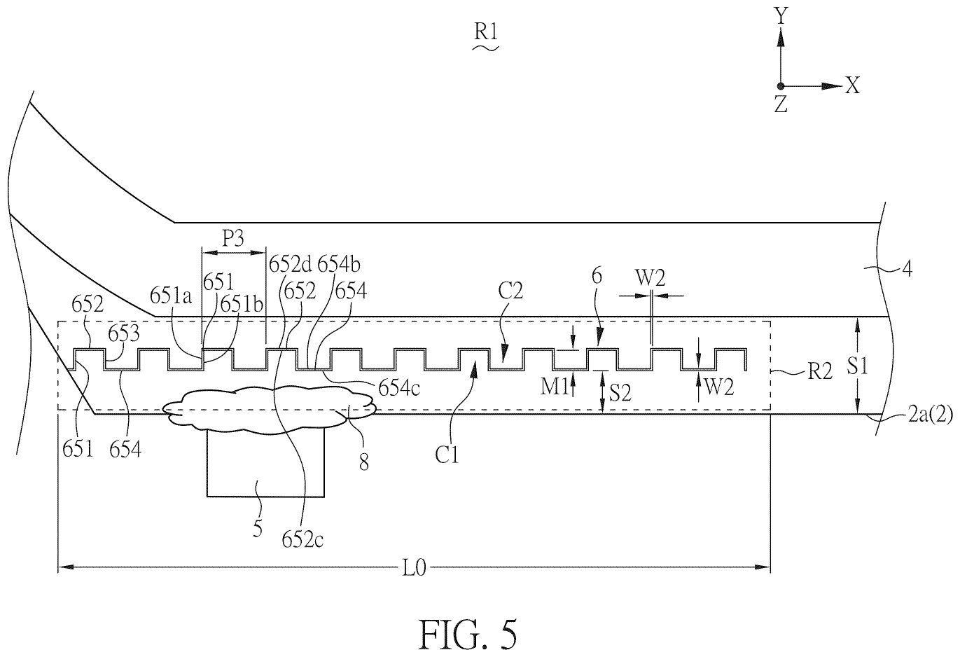

The wall structure 6 of the present disclosure may also have different implementation aspects, and please refer to FIG. 1 to FIG. 5 at the same time. FIG. 5 is a detailed schematic diagram (top view) of the first region R1 of the electronic device 1 in FIG. 1 according to still another embodiment of the present disclosure.

As shown in FIG. 5, when viewed in a top view direction, i.e., viewed along the third direction (Z-direction), the wall structure 6 is arranged between the sealant frame 4 and the first side 2a of the first substrate 2. In this embodiment, the wall structure 6 may be formed by connecting a plurality of walls, wherein the shape of the wall structure 6 may be similar to the waveform of a periodic signal, such as a square wave, a sine wave (not shown), a triangle wave (not shown), a saw-tooth wave (not shown), etc., while it is not limited thereto. In the following, the shape of the wall structure 6 being similar to the waveform of a square wave is taken as an example for illustration.

The wall structure 6 may include at least one first extension portion 651, at least one second extension portion 652, at least one third extension portion 653 and at least one fourth extension portion 654, wherein the first extension portion 651 and the third extension portion 653 extend in the second direction (Y-direction) and are opposite to each other, and the second extension portion 652 and the fourth extension portion 654 extend in the first direction (X-direction) and are opposite to each other. In one embodiment, the wall structure 6 includes a plurality of first extension portions 651, a plurality of second extension portions 652, a plurality of third extension portions 653 and a plurality of fourth extension portions 654, wherein a first extension portion 651 is connected to a second extension portion 652, the second extension portion 652 is connected to a third extension portion 653, the third extension portion 653 is connected to a fourth extension portion 654, the fourth extension portion 654 is connected to another first extension portion 651, and so on. In addition, in the first direction (X-direction), the third extension portion 653 may be arranged between two first extension portions 651. In the second direction (Y-direction), the second extension portion 652 is closer to the sealant frame 4 than the fourth extension portion 654. In addition, the first extension portion 651, the second extension portion 652 and the third extension portion 653 may form a first accommodating space C1, and the third extension portion 653, the fourth extension portion 654 and the another first extension portion 651 may form a second accommodating space C1, wherein the first accommodating space C1 has an opening facing the first side 2a of the first substrate 2, and the second accommodating space C2 has an opening facing the sealant frame 4. In addition, the wall placement region R2 in this embodiment may be figured out from the description of the embodiment in FIG. 3, and thus a detailed description is deemed unnecessary.

Each first extension portion 651 may have a first side 651a and a second side 651b opposite to each other. In the first direction (X-direction), there may be a shortest distance between the first side 651a of a first extension portion 651 and the first side 651a of another first extension portion 651 that is closest thereto, hereinafter referred to as the gap P3. In one embodiment, the gap P3 may be between 50 μm and 100 μm (i.e., 50 μm≤P3≤100 μm), but it is not limited thereto.

In addition, each second extension portion 652 may have a bottom side 652c and a top side 652d opposite to each other, wherein the bottom side 652c is closer to the first side 2a of the first substrate 2 than the top side 652d. Each fourth extension portion 654 may have a bottom side 654c and a top side 654d opposite to each other, wherein the top side 654d is closer to the sealant frame 4 than the top side 654c. In the second direction (Y-direction), there is a shortest distance between the bottom side 652c of the second extension portion 652 and the bottom side 654c of the fourth extension portion 654 that is closest thereto, hereinafter referred to as the level difference M1. In one embodiment, the level difference M1 may be between 50 μm and 100 μm (i.e., 50 μm≤M1≤100 μm), but it is not limited thereto.

There is a shortest distance between the sealant frame 4 and the first side 2a of the first substrate 2 (i.e., the first distance S1) in the second direction (Y-direction). In one embodiment, the first distance S1 may be between 50 μm and 200 μm (i.e., 50 μm≤S1≤200 μm), but it is not limited thereto. In addition, there is a shortest distance between the bottom side 652c of the second extension portion 652 and the first side 2a of the first substrate 2 (i.e., the second distance S2) in the second direction (Y-direction). In one embodiment, the second distance S2 may be between 20 μm and 50 μm (i.e., 20 μm≤S1≤50 μm), but it is not limited thereto.

In addition, in one embodiment, the first extension portion 651, the second extension portion 652, the third extension portion 653 and the fourth extension portion 654 may have the same wall width W2, wherein the wall width W2 may be, for example, the shortest distance between the first side 651a and the second side 651b of a first extension portion 651, or the shortest distance between the bottom side 652c and the top side 652d of a second extension portion 652, and so on. In one embodiment, the wall width W2 may be between 20 μm and 50 μm (i.e., 20 μm≤W2≤50 μm), but it is not limited thereto.

With the configuration of the embodiment of FIG. 5, the first accommodating space C1 of the wall structure 6 may be used to accommodate the conductive sealant 8, or the second accommodating space C2 of the wall structure 6 may be used to accommodate the externally expanded sealant frame 4, Therefore, it is able to improve the effect of blocking the sealant frame 4 or the conductive sealant 8.

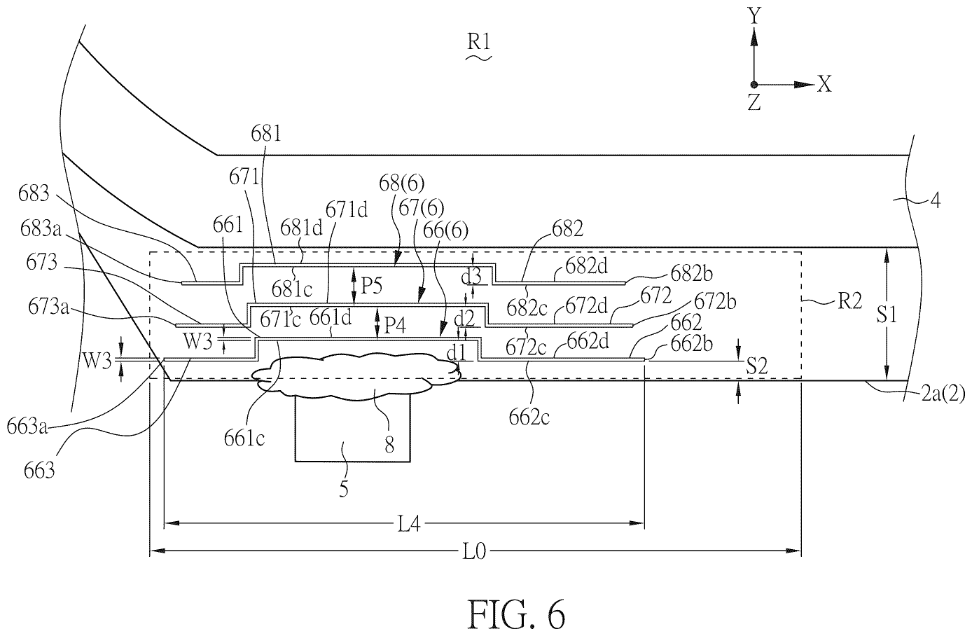

The wall structure 6 of the present disclosure may also have different implementation aspects, and please refer to FIG. 1 to FIG. 6 at the same time. FIG. 6 is a detailed schematic diagram (top view) of the first region R1 of the electronic device 1 in FIG. 1 according to yet another embodiment of the present disclosure.

As shown in FIG. 6, when viewed in a top view direction, i.e., viewed along the third direction (Z-direction), the wall structure 6 may be arranged between the sealant frame 4 and the first side 2a of the first substrate 2. In this embodiment, the wall structure 6 may include one or more walls. For example, the wall structure 6 may include a first wall 66, a second wall 67 and a third wall 68, wherein the third wall 68 is closer to the sealant frame 4 than the second wall 67, and the second wall 67 is closer to the sealant frame 4 than the first wall 66.

The first wall 66 includes a first body portion 661, a first side portion 662 and another first side portion 663, wherein the first side portion 662 and the another first side portion 663 are respectively connected to two sides of the main body portion 661. In the second direction (Y-direction), a shortest distance between the first side portion 662 and the first side 2a of the first substrate 2 may be equal to a shortest distance between the another first side portion 663 and the first side 2a of the first substrate 2. The second wall 67 includes a second body portion 671, a second side portion 672 and another second side portion 673, wherein the second side portion 672 and the another second side portion 673 are respectively connected to two sides of the second body portion 671. In the second direction (Y-direction), a shortest distance between the second side portion 672 and the first side 2a of the first substrate 2 may be equal to a shortest distance between the another second side portion 673 and the first side 2a of the first substrate 2. The third wall 68 includes a third body portion 681, a third side portion 682 and another third side portion 683, wherein the third side portion 682 and the another third side portion 683 are respectively connected to two sides of the third body portion 681. In the second direction (Y-direction), a shortest distance between the third side portion 682 and the first side 2a of the first substrate 2 may be equal to a shortest distance between the another third side portion 683 and the first side 2a of the first substrate 2.

The first body portion 661, the second body portion 671 and the third body portion 681 may have the same or similar shapes, such as a U-shaped or reverse U-shaped structure, but the present disclosude is not limited thereto. In another embodiment, the first body portion 661, the second body portion 671 and the third body portion 681 may have different shapes. In addition, the first body portion 661, the second body portion 671 and the third body portion 681 may have different sizes, for example, the second body portion 671 may surround the first body portion 661, and the third body portion 681 may surround the second body portion 671.

It is noted that the sizes, shapes, proportions and relative positions of the first wall 66, the second wall 67 and the third wall 68 shown in FIG. 6 are for illustrative purpose only, but not for limitations of the present disclosure.

In one embodiment, the first body portion 661 is closer to the sealant frame 4 than the first side portion 662 and the another first side portion 663. The first body portion 661 has a top side 661d and a bottom side 661c extending in the first direction (X-direction) and opposite to each other, and the top side 661d is closer to the sealant frame 4 than the bottom side 661c. The first side portion 662 has a top side 662d and a bottom side 662c extending in the first direction (X-direction) and opposite to each other, wherein the bottom side 662c is closer to the first side 2a of the first substrate 2 than the top side 662d. In the second direction (Y-direction), there is a shortest distance between the bottom side 662c of the first side portion 662 and the bottom side 661c of the first body portion 661, which is hereinafter referred to as the first level difference d1. In one embodiment, the first level difference d1 may be between 90 μm and 110 μm (i.e., 90 μm≤d1≤110 μm), but it is not limited thereto. In one embodiment, the first level difference d1 may be between 95 μm and 105 μm (i.e., 95 μm≤d1≤105 μm), but it is not limited thereto. In one embodiment, the first level difference d1 may be substantially 100 μm (i.e., d1=100 μm), but it is not limited thereto. The another first side portion 663 may have the characteristics of the aforementioned first side portion 662, and thus a detailed description is deemed unnecessary.

In one embodiment, the second body portion 671 is closer to the sealant frame 4 than the second side portion 672 and the another second side portion 673. The second body portion 671 has a top side 671d and a bottom side 671c extending in the first direction (X-direction) and opposite to each other, and the top side 671d is closer to the sealant frame 4 than the bottom side 671c. The second side portion 672 has a top side 672d and a bottom side 672c extending in the first direction (X-direction) and opposite to each other, wherein the bottom side 672c is closer to the first side 2a of the first substrate 2 than the top side 672d. In the second direction (Y-direction), there is a shortest distance between the bottom side 672c of the second side portion 672 and the bottom side 671c of the second body portion 671, which is hereinafter referred to as the second level difference d2. In one embodiment, the numerical range of the second level difference d2 may be figured out from the numerical range of the first level difference d1, and thus a detailed description is deemed unnecessary. The another second side portion 673 may have the characteristics of the aforementioned second side portion 672, and thus a detailed description is deemed unnecessary.

In one embodiment, the third body portion 681 is closer to the sealant frame 4 than the third side portion 682 and the another third side portion 683. The third body portion 681 has a top side 681d and a bottom side 681c extending in the first direction (X-direction) and opposite to each other, and the top side 681d is closer to the sealant frame 4 than the bottom side 681c. The third side portion 682 has a top side 682d and a bottom side 682c extending in the first direction (X-direction) and opposite to each other, wherein the bottom side 682c is closer to the first side 2a of the first substrate 2 than the top side 682d. In the second direction (Y-direction), there is a shortest distance between the bottom side 682c of the third side portion 682 and the bottom side 681c of the third body portion 681, which is hereinafter referred to as the third level difference d3. In one embodiment, the numerical range of the third level difference d3 may be figured out from the numerical range of the first level difference d1, and thus a detailed description is deemed unnecessary. In one embodiment, the first level difference d1, the second level difference d2 and the third level difference d3 may be the same, but it is not limited thereto. The another third side portion 683 may have the characteristics of the aforementioned third side portion 682, and thus a detailed description is deemed unnecessary.

In addition, in one embodiment, the first wall 66 may have a wall width W3, wherein the wall width W3 may be, for example, the shortest distance between the top side 661d and the bottom side 661c of the first body portion 661, and so on. In one embodiment, the wall width W3 may be between 20 μm and 50 μm (20 μm≤W3≤50 μm), but it is not limited thereto. In addition, the second wall 67 and the third wall 68 each may have a wall width W3. In one embodiment, the wall widths W3 of the first wall 66, the second wall 67 and the third wall 68 may be the same or different.

In addition, there may be a gap P4 between the first wall 66 and the second wall 67 in the second direction (Y-direction), wherein the gap P4 may be defined as the shortest distance between the bottom side 661c of the first body portion 661 and the bottom sides 671c of the second body 671. In one embodiment, the gap P4 may be between 30 μm and 40 μm (i.e., 30 μm≤P4≤40 μm), but it is not limited thereto. In one embodiment, the gap P4 may be between 32.5 μm and 37.5 μm (i.e., 32.5 μm≤P4≤37.5 μm), but it is not limited thereto. In one embodiment, the gap P4 may be substantially 35 μm (i.e., P4=35 μm). In addition, there may be a gap P5 between the second wall 67 and the third wall 68 in the second direction (Y-direction), wherein the gap P5 may be defined as the shortest distance between the bottom side 671c of the second body portion 671 and the bottom sides 681c of the third body portion 681. In one embodiment, the gap P5 may be between 30 μm and 40 μm (i.e., 30 μm≤P5≤40 μm), but it is not limited thereto. In one embodiment, the gap P5 may be between 32.5 μm and 37.5 μm (i.e., 32.5 μm≤P5≤37.5 μm), but it is not limited thereto. In one embodiment, the gap P5 may be substantially 35 μm (i.e., P5=35 μm). In one embodiment, the gap P4 and the gap P5 may be substantially equal (i.e., P4=P5).

In one embodiment, the first wall 66 may have a wall length L4 in the first direction (X-direction), wherein the wall length L4 is defined as the distance between the first side portion 662 and the another first side portion 663 of the first wall 66 in the first direction (X-direction), for example, the shortest distance between the side 662b of the first side portion 662 that is not connected to the first body portion 661 and the side 663a of the another first side portion 663 that is not connected to the first body portion 661. In one embodiment, the wall length L4 may be between 10 μm and 50 μm (i.e., 10 μm≤L4≤50 μm), but it is not limited thereto.

By analogy, in one embodiment, the shortest distance between a side 672b of the second side portion 672 and a side 673a of the another second side portion 673 of the second wall 67 may also be the wall length L4 (not shown in the figure), while it is not limited thereto. In addition, in one embodiment, the shortest distance between one side 682b of the third side portion 682 and one side 683a of the another third side portion 683 of the third wall 68 may also be the wall length L4 (not shown in the figure), while it is not limited thereto.

In the second direction (Y-direction), the shortest distance (first distance S1) between the sealant frame 4 and the first side 2a of the first substrate 2 may be figured out from the description of the embodiment in FIG. 3. In addition, in the second direction (Y-direction), the shortest distance between the bottom side 662c of the first side portion 662 of the first wall 66 and the first side 2a of the first substrate 2 may be regarded as the second distance S2. In one embodiment, the second distance S2 may be between 20 μm and 50 μm (20 μm≤S1≤50 μm), but it is not limited thereto.

In addition, the wall placement region R2 in this embodiment nay be figured out from the description of the embodiment in FIG. 3, and thus a detailed description is deemed unnecessary.

The wall structure 6 of the embodiment in FIG. 6 is suitable for the case where the wall placement region R2 has grooves or protrusions due to the mechanism design. For example, the shapes or positions of the body portion 661, 671, 673 of the wall structure 6 may be designed corresponding to the positions of the grooves or the protrusions, so that the wall structure 6 does not overlap the grooves or the protrusions in the third direction (Z-direction).

Therefore, the electronic device 1 of the present disclosure can be understood.

The present disclosure may at least compare the presence or absence of components in the electronic device 1, the configuration of the components and/or the parameters of the components as proofs for whether an object falls within the scope of patent protection, while it is not limited thereto. In addition, the present disclosure may perform observation at least by using an optical microscope (OM) or a scanning electron microscope (SEM).

In one embodiment, the electronic device 1 obtained in the foregoing embodiment may be used as a touch device. Furthermore, if the electronic device 1 prepared in the foregoing embodiments of the present disclosure is in the form of a display device or a touch display device, it may be applied to any product known in the art that requires a display screen to display images, such as monitors, mobile phones, notebook computers, video cameras, cameras, music players, mobile navigation devices, TVs, car dashboards, center consoles, electronic rearview mirrors, head-up displays, etc.

Accordingly, the present disclosure provides an improved electronic device, which may block at least part of the conductive sealant from infiltrating into the electronic device or at least part of the sealant frame from flowing to the external conductive member by the arrangement of the wall structure.

The features of the various embodiments of the present disclosure may be arbitrarily mixed and matched as long as they do not violate the spirit of the present disclosure or conflict with each other.

The aforementioned specific embodiments should be construed as merely illustrative, and not limiting the rest of the present disclosure in any way.

1. An electronic device having an active area and a peripheral area, comprising:
a first substrate having a first surface, a second surface opposite to the first surface, and a side surface connected between the first surface and the second surface;
a second substrate disposed opposite to the first surface of the first substrate, the second substrate having a third surface and a fourth surface opposite to the third surface;
a sealant frame disposed in the peripheral area and surrounding the active area;
a conductive member disposed on the third surface of the second substrate and in the peripheral area;
a wall structure disposed between the first substrate and the second substrate, wherein in a top view, the wall structure is disposed between the conductive member and the sealant frame;
a color layer disposed on the first surface of the first substrate; and
a conductive sealant comprising:
a first part disposed on the second surface of the first substrate;
a second part disposed on the side surface of the first substrate; and
a third part disposed on the conductive member, wherein the second part is connected between the first part and the third part, and in the top view, the wall structure is disposed between the third part of the conductive sealant and the sealant frame.

2. The electronic device as claimed in claim 1, further comprising:
a circuit board comprising a dummy pad; and
a conductive wire disposed on the third surface of the second substrate, wherein the conductive member is electrically connected to the dummy pad through the conductive wire.

3. The electronic device as claimed in claim 2, wherein the conductive wire is grounded.

4. The electronic device as claimed in claim 3, wherein at least a portion of the dummy pad is overlapped with the second substrate.

5. The electronic device as claimed in claim 4, wherein the dummy pad is not overlapped with the first substrate.

6. The electronic device as claimed in claim 5, wherein the circuit board comprises a conductive pad electrically connected to a signal line, and the dummy pad is insulated from the signal line.

7. The electronic device as claimed in claim 3, wherein the wall structure comprises:
a first wall part, disposed on the first surface of the first substrate; and
a second wall part, disposed on the third surface of the second substrate,
wherein in a cross-sectional view, the first wall part and the second wall part are separated.

8. The electronic device as claimed in claim 3, wherein the conductive member comprises an opening, and in a cross-sectional view, the conductive sealant is filled in the opening.

9. The electronic device as claimed in claim 3, wherein the second substrate is a thin film transistor substrate.

10. The electronic device as claimed in claim 3, wherein in the top view, the color layer is separated from the sealant frame.

11. The electronic device as claimed in claim 1, The electronic device as claimed in claim 1, wherein the wall structure comprises a first wall, a second wall and a third wall, and the second wall is disposed between the first wall and the third wall in the top view.

12. The electronic device as claimed in claim 11, wherein in the top view, the first wall extends along a first direction from a first side to a second side thereof, the second wall extends along the first direction from a first side to a second side thereof, and a shortest distance between the second side of the first wall and the second side of the second wall in the first direction is between 6 μm and 50 μm.

13. The electronic device as claimed in claim 12, wherein, in the top view, the third wall extends from a first side to a second side thereof along the first direction, and a shortest distance between the second side of the second wall and the second side of the third wall in the first direction is between 6 μm and 50 μm.

14. The electronic device as claimed in claim 11, wherein, in the top view, the first wall has a first body portion adjacent to the sealant frame and a first side portion away from the sealant frame, and a shortest distance between a bottom side of the first body portion and a bottom side of the first side portion is a first level difference; the second wall has a second body portion adjacent to the sealant frame and a second side portion away from the sealant frame, and a shortest distance between a bottom side of the second body portion and a bottom side of the second side portion is a second level difference; the third wall has a third body portion adjacent to the sealant frame and a third side portion away from the sealant frame, and a shortest distance between a bottom side of the third body portion and a bottom side of the third side portion is a third level difference, where the first level difference, the second level difference and the third level difference are equal.

15. The electronic device as claimed in claim 11, wherein the first wall has a side away from the sealant frame and a side adjacent to the sealant frame, the second wall has a side away from the sealant frame and a side adjacent to the sealant frame, and the third wall has a side away from the sealant frame and a side adjacent to the sealant frame, wherein, in the top view, a shortest distance between the side of the first wall away from the sealant frame and the side of the second wall away from the sealant frame in a second direction is between 15 μm and 20 μm, and a shortest distance between the side of the second wall away from the sealant frame and the side of the third wall away from the sealant frame in the second direction is between 15 μm and 20 μm, where the second direction is different from a direction of the top view.

16. The electronic device as claimed in claim 11, further comprising a side wall disposed obliquely when viewed in the top view, wherein the first wall, the second wall and the third wall are connected to different positions on the side wall.

17. The electronic device as claimed in claim 1, wherein the wall structure is formed by connecting a plurality of walls, and has a shape of periodic signal waveform;
wherein the wall structure includes a plurality of first extension portions, a plurality of second extension portions, a plurality of third extension portions and a plurality of fourth extension portions, in which a first extension portion is connected to a second extension portion, the second extension portion is connected to a third extension portion, the third extension portion is connected to a fourth extension portion, and the fourth extension portion is connected to another first extension portion;
wherein each of the first extension portions has a first side a and a second side opposite to each other, there is a gap between the first side of the first extension portion and the first side of another first extension portion closest thereto in a first direction, and the gap is between 50 μm and 100 μm, wherein the first direction is different from a direction of the top view.

18. The electronic device as claimed in claim 17, wherein each of the second extension portions has a bottom side and a top side opposite to each other, each of the fourth extension portions has a bottom side and a top side opposite to each other, there is a level difference between the bottom side of the second extension portion and the bottom side of the fourth extension portion closest thereto in a second direction, and the level difference is between 50 μm and 100 μm, where the second direction is different from the first direction and the direction of the top view.
